(19) United States
(12) Patent Application Publication
(10) Pub. No.: US 2004/0196089 A1
(43) Pub. Date: Oct. 7, 2004

(54) Switching device

(76) Inventors: John J. O'Donnell, Quin (IE); Martin G. Cotter, Ennis (IE)

Correspondence Address: WOLF GREENFIELD & SACKS, PC, FEDERAL RESERVE PLAZA, 600 ATLANTIC AVENUE, BOSTON, MA, 02210-2211, US

(21) Appl. No.: 10/405,384

(22) Filed: Apr. 2, 2003

(51) Int. Cl. H03K 17/687

(52) U.S. Cl. 327/437

(57) ABSTRACT

The invention provides an analog switching device adapted to compensate for the effects of high frequency input signals. By providing a high pass filter between the input or output nodes and the control node it is possible to effectively introduce a portion of the high frequency component of the input signal to the control node, thereby reducing the differential between the nodes.

The invention relates to an electronic switching device and in particular to an analog switch adapted to compensate for the distortion that typically occurs when operating at high input signal frequencies.

### BACKGROUND TO THE INVENTION

Analog switches are well known in the art and are typically implemented using MOS or bipolar technologies. Ideally, an analog switch when switched on should provide unity voltage gain for a range of input voltages operating at a range of frequencies. FIGS. 1a to 1c show schematic diagrams of current implementations of such a switch as provided by a purely n-type transistor 100, a p-type transistor 105 and a combination of both n- and p-type transistors 110 connected in parallel respectively.

In reality the characteristics of an analog switch when implemented as shown in FIGS. 1a-1c differ from that of an ideal switch due to the inherent “on-resistance” associated with such switch implementations, and thus the performance of these switches is not ideal. This “on-resistance” has the added problem in that it varies with applied input voltage.

FIGS. 2a-2c show typical graphs of a plot of the switch resistance as a function of input voltage Vin, for the switch implementations of FIGS. 1a to 1c. It will be appreciated for n-type transistor switches, as shown in FIG. 2a, the resistance value is low until the input voltage approaches the operating voltage (3.3V typically) of the switch, i.e. one threshold voltage (V_{T}) below the gate, at which stage it gradually increases to a high resistance value. FIG. 2b shows that for p-type transistor switches the resistance is high until the input voltage approaches the operating voltage of the switch, i.e. one threshold voltage (V_{T}) above the gate, and decreases as the value of the input voltage exceeds the operating voltage. For both n-type and p-type transistors, it will be appreciated that the switch is barely on for input voltages that differ from the gate voltage by the threshold voltage of the transistor device that realises the switch, and is off for input voltages that differ from the gate voltage by less than the threshold voltage. This is due to the high “on-resistance” present at this region of operation.

The implementation of a switch realised by the combination of the two types of transistor device is common as it provides a relatively flat on-resistance value for a wide range of input voltages, as shown in FIG. 2c. This is due to the fact that any change in the input voltage will vary the resistance of both n- and p-type transistor devices in opposing directions as described above, so that the increase in the resistance of one transistor device is compensated to some degree by a decrease in the resistance of the other device.

This variation of switch on-resistance with input voltage causes specific problems with linearity where there are parasitic capacitances or inductances at the input or output nodes of the switch. This is because the transfer characteristic of the system is influenced not only by the transistor device itself, but also by the parasitic capacitances or inductances at the input or output nodes of the switch. In the case where the dominant parasitic is the capacitance at the switch output, the transfer characteristic of the system is an RC transfer characteristic that varies as the switch resistance changes, i.e. as the input signal changes. The problems caused by this variation become more severe at higher input signal frequencies because the gain of an RC network becomes more dependent on the transfer characteristic as frequency increases. The result is increased signal distortion.

A transfer characteristic for the implementation of a switch as shown in FIGS. 1a to 1c may be plotted by calculating the gain of the switch over a range of input signal frequencies for a constant value of signal voltage. FIG. 3 demonstrates the variation of the transfer characteristic of such switches for different applied signal voltages. It can be seen that the transfer characteristic is an RC transfer characteristic, caused by the switch resistance and the inherent or parasitic capacitance on the capacitor output. It will be appreciated that at low signal frequencies, the gain is relatively constant and independent of the applied input voltage but, as the signal frequency increases the gain drops for the same applied input voltage, and as the applied input voltage is varied at high frequencies, the difference in gain for different values of applied input voltage is considerable. As ideally the gain of the switch should be the same regardless of the applied input voltage and its frequency of operation, this distortion is unsuitable for applications that require high frequencies of operation, for example in applications operating in Mega or Gigahertz frequency ranges.

Problems associated with the inherent “on-resistance” of the switch are more evident when one reduces the supply voltages at which the switch is being used, as the on-resistance of a switch increases with decreasing supply voltage. FIGS. 4a to 4c show a graph of resistance versus input voltage for switch operating voltages of 5V, 3.3V and 1V. It will be appreciated that the performance deteriorates as one reduces the operating voltage, to a worst case scenario (FIG. 4c) where the switch will not operate. This failure can be traced to the fact that at the lower values of operating voltage, the value of the gate source voltage of the transistor device will in turn be reduced. As the electronics industry moves towards lower operating voltages, it is paramount that this problem should be addressed.

A further problem may arise from a fourth node called the backgate or body that is present in the transistors typically used to implement analog switches. The presence of this node gives rise to what is known as the backgate effect. The backgate effect is a phenomenon where the threshold voltage becomes a function of the body to source voltage, Vbs. This is an undesirable feature, as it results in the reduction of the effective gate voltage of such a switch and the increase in the on-resistance.

Various solutions have been formulated which attempt to linearize switch operation over the entire frequency range of operation.

One approach is the use of a larger switch, thereby effecting a reduction of the on-resistance. The increase in the switch size lowers the switch on-resistance, but when a switch is operating as part of a multiplexor the increased size has the effect of increasing the load capacitance, due to all the off switches connected at the multiplexor output, which is not desirable.

Another approach is to implement a switch using depletion mode MOSFET devices, rather than the conventionally used enhancement mode MOSFET devices. In a depletion device, the switch is turned on when the voltage between the gate and the source is 0V, which therefore overcomes the previously identified problems. However, the drawback of such a circuit is that the cost of implementing a depletion mode MOSFET in silicon is far greater than the cost associated with implementing an enhancement mode device in silicon.

Two US patents, namely U.S. Pat. No. 6,118,326 entitled “Two-Phase Bootstrapped CMOS switch drive technique and circuit” and U.S. Pat. No. 5,945,872 entitled “Two-Phase Boosted CMOS switch drive technique and circuit”, both assigned to the assignee of the present invention, describe circuits that aim to control the voltage level of a gate drive signal of a MOSFET switch. U.S. Pat. No. 6,118,326 describes the boosting of the supply voltage to produce the gate drive voltage for a device. While this does result in the reduction of the on-resistance of the device, it does not flatten the on-resistance in the operating region. U.S. Pat. No. 5,945,872 describes the gate drive voltage being bootstrapped to a boosted level of the input voltage below the breakdown voltage of the device to maintain a relatively constant on-resistance of the device. However, this second patent seeks to maintain a constant gate to source voltage over all frequencies, and works better at lower frequencies with performance falling away at higher frequencies. The circuits described in these two patents also require additional voltages in order to bootstrap the gate drive of the switch, and as the generation of a voltage on a circuit is not easily achieved when a circuit is not switching frequently, these are difficult to implement.

Another US patent, U.S. Pat. No. 6,154,085, entitled “Constant gate drive MOS analog switch”, describes a circuit which is designed to provide a constant gate drive MOS switch regardless of the input signal. The described switch includes 3 NMOS transistor devices and a level shifter. The level shifter provides a constant gate drive to the first device, regardless of a signal on the input terminal, by levelshifting the input voltage and applying it to the gate of the device so as to maintain a constant gate source voltage. This results in a constant on-resistance of the analog switch. In addition, a constant linearity of on-resistance is achieved by keeping the gate voltage constant with respect to the mid-point of the source and drain voltages. However there are a number of drawbacks associated with this circuit. Firstly, it requires a plurality of components for operation (3 transistors and a level shifter). The circuit also requires a separate supply voltage for the level shifter which is higher than the chip supply. This is expensive to generate and consumes power. Additionally, this circuit is designed to operate at low frequencies and will not operate above a certain frequency, which is determined by the bandwidth of the level shifter. This is a major disadvantage in a field where the move is towards higher frequencies of operation.

Accordingly there is a need to provide an improved switching device which will overcome the problems associated with the prior art.

### SUMMARY OF THE INVENTION

These needs and other are addressed by the present invention which provides a switching device which is adapted to compensate for high frequency distortion effects in the operation of the device.

In accordance with a first embodiment of the present invention, a switching device is provided having a transistor with an input node, an output node and a control node, the device being adapted to couple a signal between the input and output nodes upon application of an activating voltage to the control node and wherein the device further includes a high pass filter provided between the control node and one of the input or output nodes to compensate for device on-resistance variations at high frequencies.

The high pass filter may be provided or effected by a connection of a resistor between the activating voltage and the control node.

The high pass filter may also be provided or effected by a driving of the control node with a voltage source with a high output impedance.

The output impedance of the voltage source typically should be greater than about 50 k Ohms.

In a favoured construction, the high pass filter is effected by a connection of a resistor between the activating voltage and the control node and a capacitor between the input and control nodes.

Alternatively, the high pass filter is effected by a connection of a resistor between the activating voltage and the control node and a capacitor between the output and control nodes.

Preferably, the switching device further comprises a capacitor connected between the input and control nodes. Alternatively, the switching device further comprises a capacitor connected between the output and control nodes.

Desirably, the transistor is a CMOS transistor. The transistor is typically a MOS transistor and the input node, the output node and the control node are the drain, source and gate of the MOS transistor. The MOS transistor may be a PMOS type device. Alternatively the MOS transistor may be a NMOS type device.

In certain embodiments, the input signal may additionally be coupled to the backgate of the MOS transistor when the transistor is on.

The switching device may further including a second transistor, the second transistor having an input node, an output node and a control node and adapted to couple a signal between the input and output nodes upon application of an activating voltage to the control node, the second transistor including a second high pass filter provided between the control node and one of the input or output nodes, wherein the first transistor is provided in an NMOS configuration and the second transistor is provided in a PMOS configuration, and wherein the high pass filters coupled to the first and second transistors provide for a compensation for the device on-resistance variations at high frequencies.

Desirably the value of the activating voltage applied to the control node of the PMOS transistor is the complement of the value of the activating voltage applied to the control node of the NMOS transistor.

The input signal may further be coupled to the backgate of the PMOS and NMOS transistors, the input signal being coupled to the backgate of the PMOS and the backgate of the NMOS transistor when the transistors are on.

The transistors may also be formed from bipolar devices.

In accordance with a further embodiment, the present invention also provides a switching device having a transistor and adapted to compensate for the effect of high frequency distortion, the device providing for the controlled coupling of an input signal applied to an input node to an output node upon application of a desired control signal to a control node, the device further providing filter components provided between one of the input and output nodes and the control node, the filter components effecting the formation of a high pass filter, the filter adapted to effect a coupling of a portion of a signal at one of the input or output nodes respectively to the control node thereby maintaining the voltage difference between the control node and one of the input or output nodes respectively substantially constant during high frequencies of operation of the device.

The filter components typically include resistive and capacitive components. The capacitive component may be provided by an inherent capacitance associated with the transistor. Preferably, the capacitive component is provided by a capacitor connected between the control node and the input node. Alternatively, the capacitive component may be provided by a capacitor connected between the control node and the output node. Preferably, the resistive component is provided by a resistor connected between an activating voltage and the control node.

The present invention also provides a transistor provided in a switch configuration, the transistor having a source, a gate and a drain and adapted to couple a signal between the drain and source upon application of an activating voltage to the gate and wherein the transistor further includes a high pass filter provided between the gate and one of the source or drain such that it effects an increase in the signal at the gate at high frequencies.

The present invention also provides a switching device having a first transistor and a second transistor, each transistor having an input node, an output node and a control node and adapted to couple a signal between the input and output nodes upon application of an activating voltage to the control node and wherein the device further includes a high pass filter provided between each control node and one of each of the input or output nodes to compensate for device on-resistance variations at high frequencies, and wherein the first transistor is provided in an NMOS configuration and the second transistor is provided in a PMOS configuration.

The input signal may further be coupled to the backgate of the PMOS and NMOS transistors comprising the device, the input signal being coupled to the backgate of the PMOS transistor and to the backgate of the NMOS transistor when the transistors are on, thereby reducing backgate effects associated with the device.

In yet a further embodiment, the present invention also provides a method of compensating for the effect of high frequency signal distortion in a switching device having an input node, an output node and a control node, the method comprising the step of:

a) providing a high pass filter between either the input node/control node or output node/control node pairing such that a high frequency component of an applied input signal is coupled to the control node of the device thereby minimizing the “on” resistance variation of the device.

These and other features of the present invention will be better understood with reference to the following drawings.

### BRIEF DESCRIPTION OF THE DRAWINGS

FIG. 1a shows a schematic diagram of an n-type transistor implementation of an analog switch in accordance with the prior art configurations,

FIG. 1b shows a schematic diagram of a p-type transistor implementation of an analog switch in accordance with the prior art configurations,

FIG. 1c shows a schematic diagram of a combination of a p-type and n-type transistor implementation of an analog switch in accordance with the prior art configurations,

FIG. 2a show a graph of resistance versus input voltage for the transistor implementation of FIG. 1a,

FIG. 2b shows a graph of resistance versus input voltage for the transistor implementation of FIG. 1b,

FIG. 2c shows a graph of resistance versus input voltage for the transistor implementation of FIG. 1c,

FIG. 3 shows a plot of the gain versus input signal frequency for such switch implementations as shown FIGS. 1a-1c for a range of applied input signal voltages;

FIG. 4a shows a graph of resistance versus input voltage for a switch with a supply voltage of 5V,

FIG. 4b shows a graph of resistance versus input voltage for a switch with a supply voltage of 3.3V,

FIG. 4c shows a graph of resistance versus input voltage for a switch with a supply voltage of 1V,

FIG. 5 shows a schematic diagram for a n-type analog switch in accordance with a first embodiment of the present invention,

FIG. 6 shows an alternative schematic diagram for n-type analog switch in accordance with a second embodiment of the present invention,

FIG. 7 shows a schematic diagram for a combination of a p-type and n-type transistor implementation of an analog switch in accordance with a third embodiment of the present invention,

FIG. 8 shows a schematic diagram for a combination of a p-type and n-type transistor implementation of an analog switch in accordance with a fourth embodiment of the present invention,

FIG. 9 show a typical plot of gain versus frequency for a high pass filter,

FIGS. 10a-c shows a graph of the measured input and gate voltages for a 100 kHz, 1 MHz and 10 MHz input signal for an analog switch according to the present invention,

FIG. 11 shows a graph of on-resistance versus input voltage for a signal operating at less than 100 kHz, at 10 MHz and at 100 MHz for an analog switch of the present invention,

FIG. 12 shows typical plots of the input switch distortion over frequency for the case when the backgate is driven by the input signal to the switch and when the backgate is not driven,

FIG. 13 shows a schematic diagram for a n-type analog switch in accordance with a fifth embodiment of the present invention;

FIG. 14 shows a schematic diagram for a n-type analog switch in accordance with a sixth embodiment of the present invention, and

FIG. 15 shows in schematic form an analog switch in accordance with a seventh embodiment of the present invention.

### DETAILED DESCRIPTION OF THE DRAWINGS

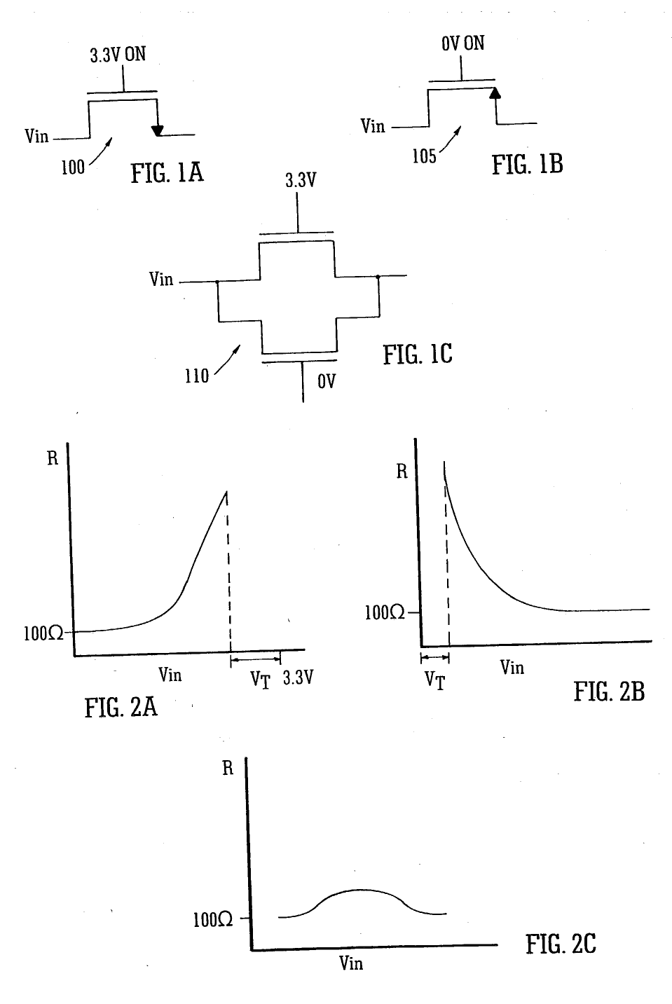

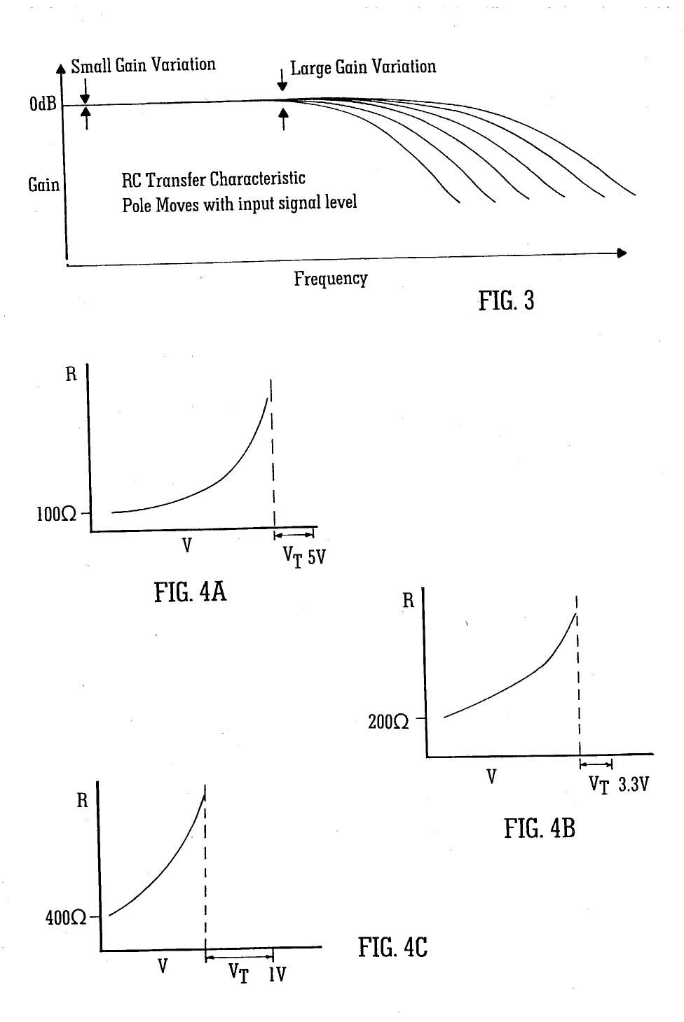

FIGS. 1 to 4 have been described with reference to the prior art.

For the ease of explanation the present invention will be described with reference to MOS technology and specifically to NMOS and CMOS type devices, although it will be appreciated by those skilled in the art that the switch can be implemented in a similar manner for a PMOS device.

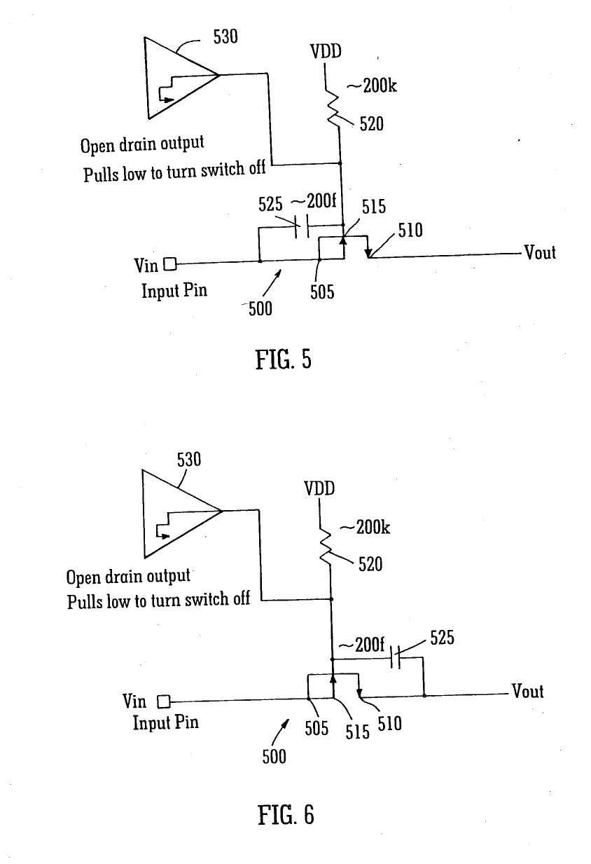

FIGS. 5, 6, 13 and 14 show implementations of switches using a NMOS device in accordance with the present invention. For the sake of convenience and ease of explanation, the same reference numerals have been used for the same components in all Figures. It will be understood that any and all component values detailed in the figures are typical values only, and it is not intended to limit the present invention to any one set of characteristics.

As shown in FIG. 5, a switching device 500 of the present invention includes an input node 505, an output node 510 and a control node 515. In the circuit of FIG. 5 the input node 505 is the drain of a MOS transistor device, the output node 510 is the source of the MOS device and the control node 515 is the gate of the MOS device. A signal applied to the input node will be coupled to the output node on application of a control signal to the control node.

The present invention provides for a modification to prior art switches so as to provide a high pass filter between the gate and source or gate and drain of the transistor device that realises the switch. It will be appreciated that there are many implementations to a high pass filter that may be employed but in the preferred embodiments as shown in the schematics of FIGS. 5, 13 and 14, it is provided by tying the gate 515 to a supply high (VDD) via a resistor 520 and connecting a capacitor 525 between the gate 515 and the drain 505. An alternative embodiment, as shown in the schematic of FIG. 6, is to tie the gate 515 to a supply high (VDD) via a resistor 520 and connecting a capacitor 525 between the gate 515 and the source 510. A control device 530 may also be electrically connected or coupled to the gate 515 and in the configurations shown in these figures it is pulled low so as to turn the switch off.

The capacitance value provided by the capacitor 525 is explicitly shown in FIGS. 5 6, 13 and 14. However, it will be appreciated by those skilled in the art that as a capacitance is inherently present in the switch device due to parasitic capacitances, a high pass filter may be created simply by the addition of a large resistor value between the supply rail VDD and the gate 515. Although, this inherent capacitance may provide a high pass filter of certain quality and as such may be suitable for certain applications, in preferred embodiments an actual physical capacitor should be added, as shown in FIGS. 5 and 6, to achieve best results.

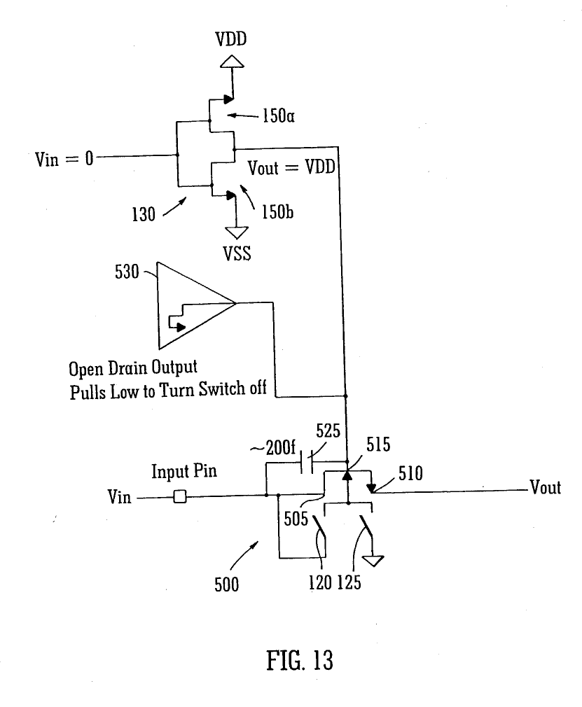

In a preferred embodiment, a resistor 520 is used to set the DC level of the gate voltage to the supply rail for the NMOS device. However it will be appreciated by those skilled in the art that a voltage source or driver 130 having a high output impedance (typically an impedance greater than 50 kOhm), which is in essence a weak voltage driver, could alternatively provide a similar resistive effect. This is illustrated in the exemplary embodiment of FIG. 13 where a weak driver is created by using 2 small sized CMOS devices 150a, 150b which provide high output impedance. The capacitor 525 couples the AC component of the input signal onto the gate 515. This AC coupling keeps the gate source voltage constant at high frequencies, which in turn flattens the on-resistance characteristic for high signal frequencies.

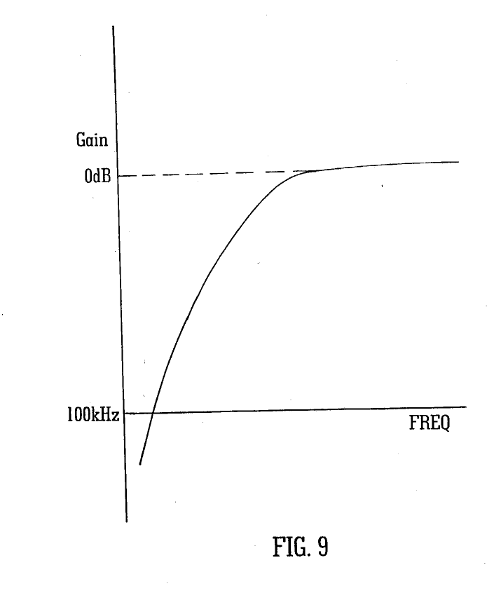

This combination of a capacitor and resistor effects the formation of a high pass filter. FIG. 9 shows a graph of the gain versus frequency which would be typical for a high pass filter. It can been seen that a high pass filter blocks low frequency signals while allowing high frequency signals to pass through.

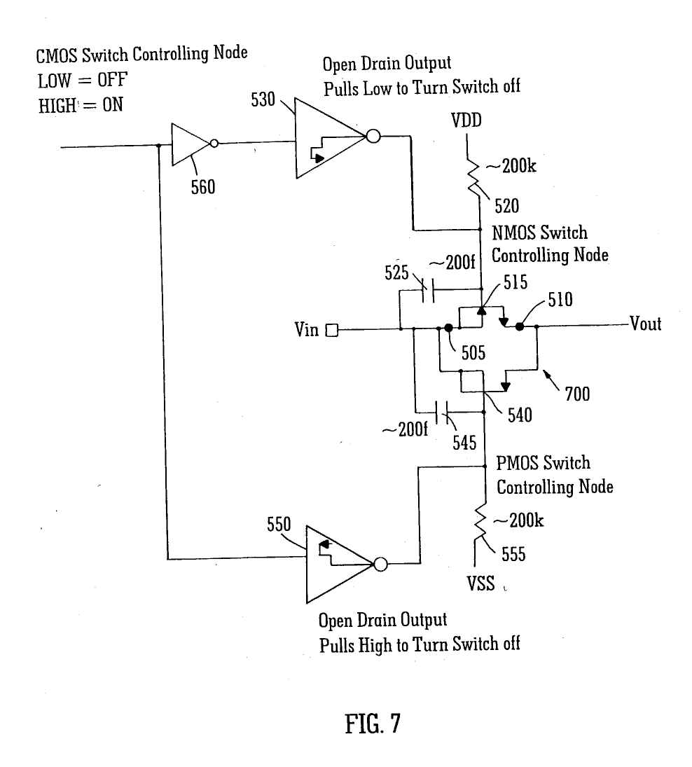

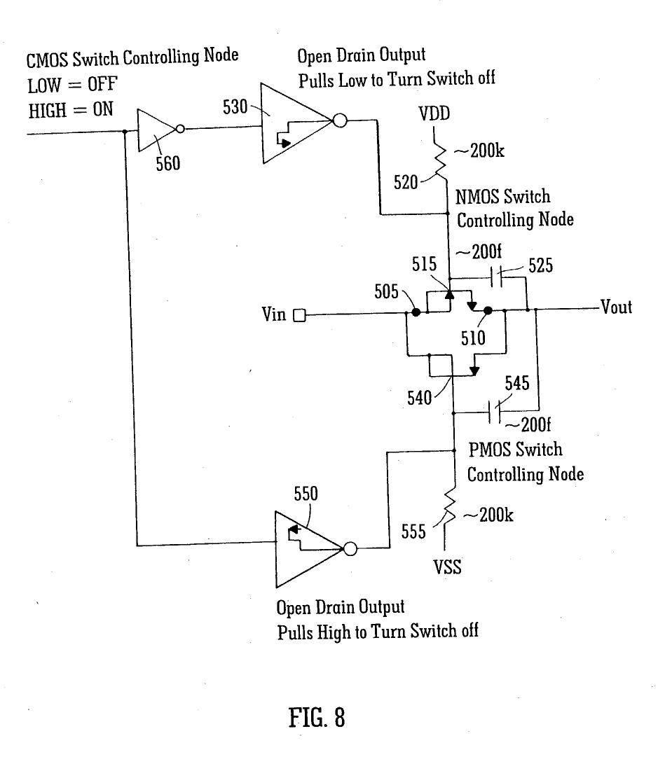

FIGS. 7 and 8 show schematic diagrams of an embodiment of the analog switch of the present invention when implemented in a combined p-type and n-type transistor analog switch. The present invention, when implemented in such a combined n-type and p-type switch, provides two high pass filters, one high pass filter being provided between each of two control nodes and either an input or an output node.

The embodiment of FIG. 7 is similar to the circuit of FIG. 5, but with the addition of a PMOS transistor 700 and its associated circuitry, so as to implement a combined p-type and n-type analog switch. The circuit includes an input node 505, an output node 510 and two control nodes 515 and 540. In the circuit of FIG. 7 the input node 505 is coupled to the drain of both the PMOS and NMOS devices and the output node 510 is coupled to the source of both the PMOS and NMOS devices. In this embodiment therefore the PMOS and NMOS devices share both a common source and a common drain, while the gates of the PMOS and NMOS devices remain independently controllable. The NMOS device control node 515 is the gate of the NMOS device, while the PMOS device control node 540 is coupled to the gate of the PMOS device.

In this embodiment of FIG. 7 the implementation of the present invention in a combined p-type and n-type transistor analog switch, the first high pass filter is provided to the NMOS transistor by tying its gate 515 to a supply high (VDD) via a resistor 520 and connecting a capacitor 525 between the gate 515 and the drain 505, while the second high pass filter is provided to the PMOS transistor by tying its gate 540 to a supply low (VSS) via a resistor 555 and connecting a capacitor 545 between the gate 540 and the drain 505. Two control devices 530 and 550 may also be electrically connected or coupled to the gates 515 and 540 so as to turn the combination p-type and n-type switch on and off. In the configuration shown in FIG. 7, when control device 530 is pulled low and control device 550 is pulled high the switch is turned off. The control devices operate in such a manner to ensure that the PMOS and NMOS devices of the switch are always simultaneously either on or off. An inverter 560 is used to invert the value of the control signal so as to provide the required control signal logic level to the control devices 530 and 550.

The embodiment of FIG. 8 is similar to the embodiment of FIG. 7, but with the high pass filters being provided between the controlling nodes and the output node, rather than the controlling nodes and input node. In this embodiment, capacitor 525 is connected between the controlling node 515 and the output node 510, while capacitor 545 is connected between controlling node 540 and the output node 510.

As in the case of the previous embodiments, as a capacitance is inherently present in the switch device due to parasitic capacitances, it will be appreciated that a high pass filter may be created in a combined n-type and p-type transistor switch simply by the addition of a large resistor value between each of the supply rail VDD and VSS and the gates 515 and 540. Similarly, it will be appreciated that a voltage source or driver having a high output impedance (typically an impedance greater than 50 kOhm), which is in essence a weak voltage driver, could be used instead of each resistor 520 and 555.

It will be appreciated that as the present invention integrates a high pass filter with an typical analog switch of the prior art, the benefit of the arrangement of the present invention occurs at high frequencies. As previously discussed in the section Background to the Invention, it is at high frequencies that the prior art had limited success in providing a switch that had a constant gain over a range of input voltages.

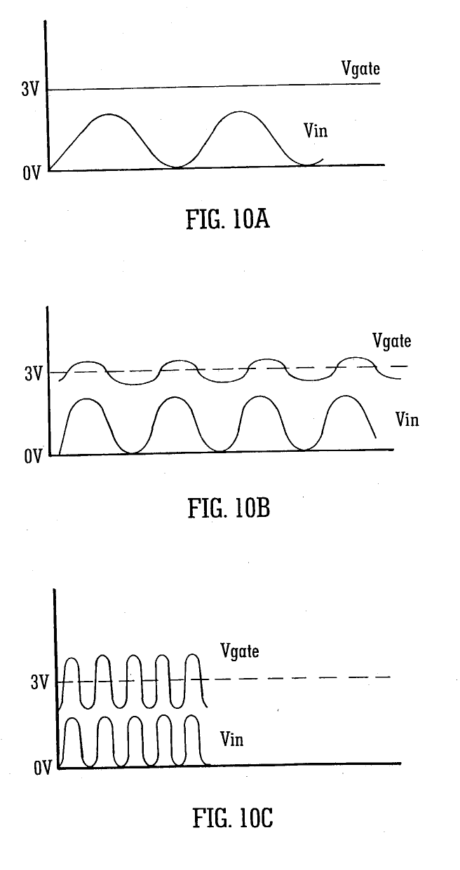

FIGS. 10a-10c shows graphs of the measured input and gate voltages for the circuits of FIGS. 5 and 6 for three examples of varying input signal frequency. FIG. 10a shows that at low input signal frequencies the high pass filter substantially blocks the AC component of the input voltage so that substantially none of the AC component of the signal is coupled onto the gate. The result is that, unlike prior art circuits, no compensation is provided for a varying input signal. However, as explained previously, the variation in gain for a varying input signal is negligible at low input frequencies. The benefit of the provision of the high pass filter is at higher frequencies.

As shown in FIG. 10b as the input frequency is increased, a portion of the AC component of the input voltage is coupled onto the gate, resulting in some compensation for a varying signal. The coupling keeps the gate source voltage of the transistor device relatively constant at these higher frequencies, and therefore minimises the on-resistance variation, which in turn reduces operating distortion. In the same manner, when the input frequency is further increased, as shown in the graph of FIG. 10c, substantially all of the AC component of the signal appears on the gate, again compensating for the distortion that would otherwise occur for a varying input signal.

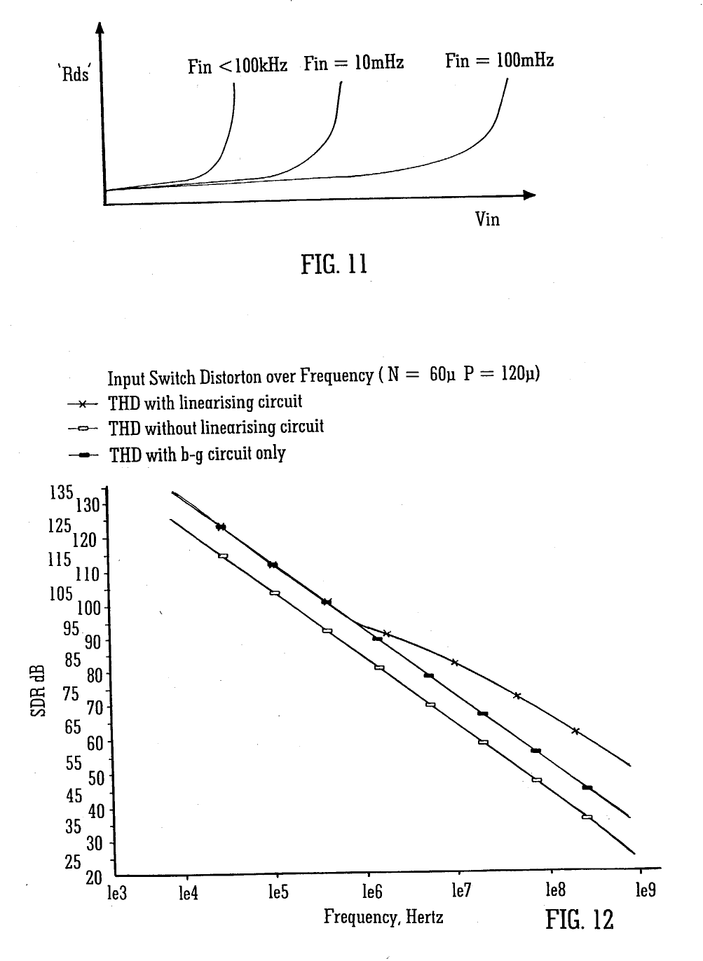

FIG. 11 illustrates the effect that the addition of a high pass filter has on the on-resistance (Rds) of a typical analog switch for an NMOS device: i.e. the effect of the present invention. It shows a graph of the resistance versus input voltage for a signal operating at less than 100 kHz, at 10 MHz and at 100 MHz as described above. It can be seen that as the input frequency gets higher, the “on” range of the device increases. It will be appreciated therefore that the present invention provides for a solution that differentiates between the frequency contributions of the applied signal, such that the low frequency effects are not compensated whereas those resultant from the high frequency components are.

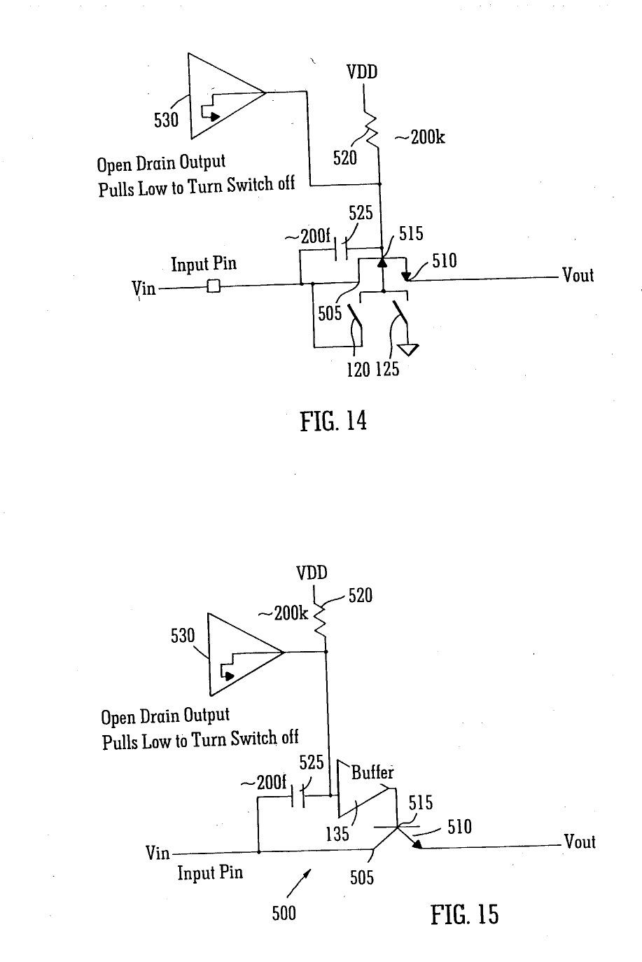

In accordance with other embodiments of the present invention, as shown in FIGS. 13 and 14, the output distortion of an analog switch is further reduced by reducing the backgate effect that is present in such analog switches, in conjunction with the provision of the high pass filter as previously described. The reduction of the backgate effect will eliminate modulation of both the threshold voltage and the on-resistance by the body to source voltage. To reduce the backgate effect, the backgate of each transistor that makes up the analog switch should be driven by the input voltage when that transistor is on, and driven by a voltage less than that required to forward bias the backgate to source junction of that transistor when it is off, i.e. by a voltage which would switch on a parasitic diode. Therefore, in accordance with this embodiment of the invention the backgates are driven by the input voltage when the transistor operating the switch is on. In accordance with the exemplary embodiment of FIG. 14, this would be achieved by closing switch 120 and opening switch 125 when the switching device is on. However, when the transistor operating the switch is off, the backgate is driven by VDD in the case of a PMOS transistor and by VSS for an NMOS transistor. In accordance with the embodiment of FIG. 14, this would be achieved by opening switch 120 and closing switch 125 when the switching device is off.

FIG. 12 shows typical plots of the input switch distortion over frequency for two examples. In a first case the backgate is driven by the input signal to the switch and in the other case the backgate is not driven. It will be appreciated from examination of this figure that the driving of the backgates in accordance with the present invention, results in a significant reduction in output distortion.

It will be appreciated that the present invention has been described with reference to CMOS type devices, and for the most part with respect to an n-type structure. It will be readily appreciated by the person skilled in the art that the provision of a high pass filter between nodes of a switch, as is provided by the present invention is not limited to the specific type of switch architecture and can be equally applied in bipolar type environments as to the CMOS scenario hereintobefore described. FIG. 15 is an exemplary schematic of the analog switch of the present invention as implemented in bipolar technology. It will be appreciated that the NMOS transistor of FIGS. 5, 6, 13 and 14 has been replaced by a bipolar transistor. The input node 505 is now the collector of the bipolar device, the output node 510 is the emitter, and the control node 515 is the base. A buffer 135 drives the base 515.

It will be appreciated therefore that the present invention provides for a solution to the problems addressed by prior art implementations in a manner hereintobefore not envisaged. In accordance with the present invention the frequency contributions of the applied signal are differentiated. In accordance with the architecture provided by the present invention, the low frequency effects are not compensated whereas those resultant from the high frequency components are. In a typical prior art switch, the resistance of the switch and the parasitic capacitance present in the switch form a low pass filter, which would typically have a cutoff frequency in the range of 500 MHz to 1 GHz. The high pass filter formed by the capacitor 525 and resistor 520 of the present invention has a 3 dB high pass filter frequency of about 4 MHz, when capacitor 525 has a value of 200 f and resistor 520 has a value of 200 k. This means that the present invention provides a benefit to the switches of the prior art at and above about 1 MHz.

This is advantageous in many applications where it is required that the switch can operate at high input frequencies without signal distortion including for example analog front end switches, analog multiplexors, radio frequency front ends and tuners.

It will be appreciated that the application of the technique of the present invention would also be advantageous in all low voltage applications and those applications where generating a bootstrap supply is simply unfeasible. It will be further appreciated that incorporation of a high pass filter into a switching device, as is provided by the present invention, also lends itself to smaller switch sizes. Although the present invention has been described with reference to specific embodiments, it will be understood by those skilled in the art that these described embodiments are exemplary of the application and technique of the present invention and it is not intended to limit the present invention to any one embodiment or combination of integers except as may be deemed necessary in the light of the appended claims. Furthermore one or more integers from any one described embodiment may be utilised in combination with any other integer from other embodiments without departing from the spirit and scope of the present invention.

1. A switching device having a transistor with an input node, an output node and a control node and adapted to couple a signal between the input and output nodes upon application of an activating voltage to the control node and wherein the device further includes a high pass filter provided between the control node and one of the input or output nodes to compensate for device on-resistance variations at high frequencies.

2. A switching device as claimed in claim 1 wherein the high pass filter is effected by a connection of a resistor between the activating voltage and the control node.

3. A switching device as claimed in claim 1 wherein the high pass filter is effected by a driving of the control node with a voltage source with a high output impedance.

4. A switching device as claimed in claim 1 wherein the high pass filter is effected by a connection of a resistor between the activating voltage and the control node and a capacitor between the input and control nodes.

5. A switching device as claimed in claim 1 wherein the high pass filter is effected by a connection of a resistor between the activating voltage and the control node and a capacitor between the output and control nodes.

6. A switching device as claimed in claim 3 further comprising a capacitor connected between the input and control nodes.

7. A switching device as claimed in claim 3 further comprising a capacitor connected between the output and control nodes.

8. A switching device as claimed in claim 3, wherein the output impedance is greater than about 50 k Ohms.

9. A switching device as claimed in claim 1 wherein the transistor is a CMOS transistor.

10. A switching device as claimed in claim 1 wherein the transistor is a MOS transistor and the input node, the output node and the control node are the drain, source and gate of the MOS transistor.

11. A switching device as claimed in claim 10 wherein the MOS transistor is a PMOS type device.

12. A switching device as claimed in claim 10 wherein the MOS transistor is a NMOS type device.

13. A switching device as claimed in claim 10 wherein the input signal is additionally coupled to the backgate of the MOS transistor when the transistor is on.

14. A switching device as claimed in claim 1 further including a second transistor, the second transistor having an input node, an output node and a control node and adapted to couple a signal between the input and output nodes upon application of an activating voltage to the control node, the second transistor including a second high pass filter provided between the control node and one of the input or output nodes, The first transistor being provided in an NMOS configuration and the second transistor in a PMOS configuration, and wherein the high pass filters coupled to the first and second transistors provide for a compensation for the device on-resistance variations at high frequencies.

15. A switching device as claimed in claim 14, wherein the value of the activating voltage applied to the control node of the PMOS transistor is the complement of the value of the activating voltage applied to the control node of the NMOS transistor.

16. A switching device as claimed in claim 14 wherein the input signal is coupled to the backgate of the PMOS and NMOS transistors, the input signal being coupled to the backgate of the PMOS and the backgate of the NMOS transistor when the transistors are on.

17. A switching device as claimed in claim 1 wherein the transistor is a bipolar device.

18. A switching device having a transistor and adapted to compensate for the effect of high frequency distortion, the device providing for the controlled coupling of an input signal applied to an input node to an output node upon application of a desired control signal to a control node, the device further providing filter components provided between one of the input and output nodes and the control node, the filter components effecting the formation of a high pass filter, the filter adapted to effect a coupling of a portion of a signal at one of the input or output nodes respectively to the control node thereby maintaining the voltage difference between the control node and one of the input or output nodes respectively substantially constant during high frequencies of operation of the device.

19. A switching device as claimed in claim 18, wherein the filter components include resistive and capacitive components.

20. A switching device as claimed in claim 19, wherein the capacitive component is provided by an inherent capacitance associated with the transistor.

21. A switching device as claimed in claim 19, wherein the capacitive component is provided by a capacitor connected between the control node and the input node.

22. A switching device as claimed in claim 19, wherein the capacitive component is provided by a capacitor connected between the control node and the output node.

23. A switching device as claimed in claim 19, wherein the resistive component is provided by a resistor connected between an activating voltage and the control node.

24. A transistor provided in a switch configuration, the transistor having a source, a gate and a drain and adapted to couple a signal between the drain and source upon application of an activating voltage to the gate and wherein the transistor further includes a high pass filter provided between the gate and one of the source or drain such that it effects an increase in the signal at the gate at high frequencies.

25. A switching device having a first transistor and a second transistor, each transistor having an input node, an output node and a control node and adapted to couple a signal between the input and output nodes upon application of an activating voltage to the control node and wherein the device further includes a high pass filter provided between each control node and one of each of the input or output nodes to compensate for device on-resistance variations at high frequencies, and wherein the first transistor is provided in an NMOS configuration and the second transistor is provided in a PMOS configuration.

26. A switching device as claimed in claim 25 wherein an input signal is also coupled to the backgate of the PMOS and NMOS transistors comprising the device, the input signal being coupled to the backgate of the PMOS transistor and to the backgate of the NMOS transistor when the transistors are on, thereby reducing backgate effects associated with the device.

27. A method of compensating for the effect of high frequency signal distortion in a switching device having an input node, an output node and a control node, the method comprising the step of:
a) providing a high pass filter between either the input node/control node or output node/control node pairing such that a high frequency component of an applied input signal is coupled to the control node of the device thereby minimizing the “on” resistance variation of the device.
